(19) United States
(12) Patent Application Publication
(10) Pub. No.: US 2026/0156375 A1
(43) Pub. Date: Jun. 4, 2026

(54) SOLID-STATE IMAGING DEVICE AND ELECTRONIC DEVICE

(71) Applicant: Sony Semiconductor Solutions Corporation, Kanagawa (JP)

(72) Inventor: Takayoshi Ozone, Kanagawa (JP)

(73) Assignee: Sony Semiconductor Solutions Corporation, Kanagawa (JP)

(21) Appl. No.: 18/874,682

(22) PCT Filed: Jun. 9, 2023
(86) PCT No.: PCT/JP2023/021481

§ 371 Date: Dec. 13, 2024

(30) Foreign Application Priority Data
Jun. 21, 2022 (JP) 2022-099409

(51) Int. Cl. H04N 25/11; B60R 1/20; H04N 23/55; H04N 23/84

(52) U.S. Cl. CPC H04N 25/11; B60R 1/20; H04N 23/55; H04N 23/843

(57) ABSTRACT

Provided are light detecting devices including pixel arrays having main pixels and sub-pixels. More than half of the main pixels may have clear filters, yellow color filters, or no color filters. The sub-pixels may have color filters of different colors, such as red, blue, and green color filters. Some of the main pixels may have red color filters. A processor may be used to generate image data based on signals from the main pixels and sub-pixels. Interpolation may be used to calculate intermediate main pixel signals for positions between the main pixels and intermediate sub-pixel signals for positions between the sub-pixels. The light detecting devices may be included in automotive camera systems and included in vehicles. A vehicle control system may control a vehicle based on image data generated using the light detecting device.

### TECHNICAL FIELD

The present art relates to a solid-state imaging device and an electronic device.

### CROSS REFERENCE TO RELATED APPLICATIONS

This application claims the benefit of Japanese Priority Patent Application JP 2022-099409 filed Jun. 21, 2022, the entire contents of which are incorporated herein by reference.

### BACKGROUND ART

Conventionally, there are three types of colors of color filters in solid-state imaging devices (solid-state imaging elements) such as image sensors, for example, red, green, and blue, or red, yellow, and cyan.

### CITATION LIST

### Patent Literature

PTL 1: JP 2015-65270 A

### SUMMARY OF INVENTION

### Technical Problem

In some conventional solid-state imaging device, it is difficult to increase the sensitivity and dynamic range on the low-illuminance side without increasing the pixel section in size.

The present art has been created in view of such circumstances and makes it possible to increase sensitivity and dynamic range on a low-illuminance side without increasing the size of a pixel section when the pixel section is configured of two types of pixels that differ in light-receiving areas.

### Solution to Problem

According to aspects of the disclosure, there is provided a light detecting device, comprising a pixel array comprising a plurality of main pixels and a plurality of subpixels having color filters, wherein more than half of the plurality of main pixels have clear filters, yellow color filters, or no color filters.

In some embodiments, the plurality of sub-pixels comprises a first group of subpixels having color filters of a first color, a second group of sub-pixels having color filters of a second color, and a third group of sub-pixels having color filters of a third color. In some embodiments, the color filter of the first color comprises a red color filter. In some embodiments, the color filter of the second color comprises a blue color filter and the color filter of the third color comprises a green color filter. In some embodiments, the color filter of the first color comprises a red color filter, the color filter of the second color comprises a yellow color filter, and the color filter of the third color comprises a cyan color filter. In some embodiments, a light receiving area of each main pixel of the plurality of main pixels comprises an octagonal shape. In some embodiments, each main pixel of the plurality of main pixels has a clear filter or no color filter. In some embodiments, at least one main pixel of the plurality of main pixels has a red color filter. In some embodiments, the light detecting device further comprises a column signal line extending in a column direction and a pixel control signal line extending in a horizontal direction, wherein the plurality of main pixels and the plurality of sub-pixels are arranged in a plurality of pixel columns in the column direction and a plurality of pixel rows in the horizontal direction. In some embodiments, at least one main pixel of the plurality of main pixels has a red color filter. In some embodiments, at least one main pixel of the plurality of main pixels has a red color filter and at least one main pixel of the plurality of main pixels has a blue color filter. In some embodiments, each pixel row of the plurality of pixel rows includes at least one pixel having a clear filter or no color filter. In some embodiments, each pixel column of the plurality of pixel columns includes at least one pixel having a clear filter or no color filter. In some embodiments, more than half of the plurality of main pixels have yellow color filters, at least one main pixel of the plurality of main pixels has a red color filter, and at least one main pixel of the plurality of main pixels has a cyan color filter. In some embodiments, the light detecting device further comprises a processor configured to generate image data based on signals from the plurality of main pixels and signals from the plurality of sub-pixels. In some embodiments, the processor is configured to calculate using interpolation intermediate main pixel signals for positions between main pixels of the plurality of main pixels and intermediate subpixel signals for positions between sub-pixels of the plurality of sub-pixels and the processor is configured to generate the image data based on signals from the plurality of main pixels, signals from the plurality of sub-pixels, the intermediate main pixel signals, and the intermediate sub-pixel signals.

According to aspects of the disclosure, there is provided a vehicle, comprising a light detecting device configured to generate signals, a processor configured to generate image data based on the signals from the light detecting device, a vehicle control system configured to control the vehicle based on the image data, wherein the light detecting device comprises a pixel array comprising a plurality of main pixels and a plurality of sub-pixels having color filters, wherein more than half of the plurality of main pixels have clear filters, yellow color filters, or no color filters.

According to aspects of the disclosure, there is provided an automotive camera system comprising a lens, a light detecting device, comprising a pixel array comprising a plurality of main pixels and a plurality of sub-pixels having color filters, wherein more than half of the plurality of main pixels have clear filters, yellow color filters, or no color filters and a processor configured to generate image data based on signals from the plurality of main pixels and signals from the plurality of sub-pixels.

In some embodiments, at least one main pixel of the plurality of main pixels has a red color filter. In some embodiments, the processor is configured to calculate using interpolation intermediate main pixel signals for positions between main pixels of the plurality of main pixels and intermediate sub-pixel signals for positions between subpixels of the plurality of sub-pixels and the processor is configured to generate the image data based on signals from the plurality of main pixels, signals from the plurality of sub-pixels, the intermediate main pixel signals, and the intermediate subpixel signals.

A solid-state imaging device according to the first aspect of the present art includes: a pixel array in which a plurality of pixel sections, each configured of a sub-pixel having a first light-receiving area and a main pixel having a second light-receiving area that is larger than the first light-receiving area, is arranged in a matrix, wherein a first color filter group configured of color filters of each of the plurality of sub-pixels arranged in the pixel array is configured of three types of color filters; at least some filters of a second color filter group configured of color filters of each of the plurality of main pixels arranged in the pixel array are broadband color filters that transmit light in a band including a green light band; and the ratio of the broadband color filters in the second color filter group is more than 50 percent.

In the first aspect of the present art, the pixel array is provided in which a plurality of pixel sections, each configured of a sub-pixel having a first light-receiving area and a main pixel having a second light-receiving area that is larger than the first light-receiving area, is arranged in a matrix, the first color filter group configured of color filters of each of the plurality of sub-pixels arranged in the pixel array is configured of three types of color filters; at least some filters of the second color filter group configured of color filters of each of the plurality of main pixels arranged in the pixel array are broadband color filters that transmit light in a band including a green light band; and the ratio of the broadband color filters in the second color filter group is more than 50 percent.

An electronic device according to the second aspect of the present art comprises: a solid-state imaging element configured to include: a pixel array in which a plurality of pixel sections, each configured of a sub-pixel having a first light-receiving area and a main pixel having a second light-receiving area that is larger than the first light-receiving area, is arranged in a matrix, a first color filter group configured of color filters of each of the plurality of sub-pixels arranged in the pixel array being configured of three types of color filters; at least some filters of a second color filter group configured of color filters of each of the plurality of main pixels arranged in the pixel array being broadband color filters that transmit light in a band including a green light band; and the ratio of the broadband color filters in the second color filter group being more than 50 percent; and a generation unit that generates an image by using sub-pixel signals, which are pixel signals corresponding to light received by the sub-pixels, and main pixel signals, which are pixel signals corresponding to light received by the main pixels.

In the second aspect of the present art, the pixel array is provided in which a plurality of pixel sections, each configured of a sub-pixel having a first light-receiving area and a main pixel having a second light-receiving area that is larger than the first light-receiving area, is arranged in a matrix, the first color filter group configured of color filters of each of the plurality of sub-pixels arranged in the pixel array is configured of three types of color filters; at least some filters of the second color filter group configured of color filters of each of the plurality of main pixels arranged in the pixel array are broadband color filters that transmit light in a band including a green light band; and the ratio of the broadband color filters in the second color filter group is more than 50 percent. Further, an image is generated using sub-pixel signals, which are pixel signals corresponding to light received by the sub-pixels, and main pixel signals, which are pixel signals corresponding to light received by the main pixels.

### BRIEF DESCRIPTION OF DRAWINGS

FIG. 1 is a block diagram showing an exemplary configuration of a first embodiment of an imaging device as an electronic device to which the present art is applied.

FIG. 2 shows an exemplary circuit configuration of the solid-state imaging element in FIG. 1.

FIG. 3 is a top view showing an exemplary first array of color filters in the first embodiment.

FIG. 4 is a top view showing an exemplary array of color filters when the array of the large color filter group in FIG. 3 is a Bayer array.

FIG. 5 is a top view showing an exemplary second array of color filters in the first embodiment.

FIG. 6 is a block diagram showing an exemplary configuration of a second embodiment of an imaging device as an electronic device to which the present art is applied.

FIG. 7 is a top view showing an exemplary configuration of a pixel array section of the solid-state imaging element in FIG. 6.

FIG. 8 shows intervals in the row direction and column direction of the pixel section in FIG. 2.

FIG. 9 shows intervals between adjacent main pixels arranged side by side in the array direction in FIG. 7.

FIG. 10 is a top view showing an exemplary array of color filters when the array of the large color filter group is obtained by tilting the Bayer array 45 degrees to the right.

FIG. 11 is a top view showing another exemplary first array of color filters in the second embodiment.

FIG. 12 is a top view showing another exemplary second array of color filters in the second embodiment.

FIG. 13 is a top view showing another exemplary third array of color filters in the second embodiment.

FIG. 14 is a top view showing another exemplary fourth array of color filters in the second embodiment.

FIG. 15 is a block diagram showing an exemplary schematic configuration of a vehicle control system.

FIG. 16 is an explanatory diagram showing exemplary installation positions of a vehicle exterior information detection unit and an imaging unit.

### DESCRIPTION OF EMBODIMENTS

Hereinafter, modes for carrying out the present art (hereinafter referred to as embodiments) will be described. The explanation is given in the following order: 1. First embodiment (imaging device in which the array direction of color filters of adjacent main pixels is the row direction); 2. Second embodiment (imaging device in which the array direction of color filters of adjacent main pixels is tilted 45 degrees with respect to the row direction); and 3. Example of application to mobile objects.

In the drawings referred to in the following description, the same or similar parts are denoted by the same or similar reference numerals. However, the drawings are schematic and may include portions with different dimensional relationships and ratios between the drawings.

Furthermore, the definitions of directions such as up and down in the following description are merely given for convenience of description, and do not limit the technical idea of the present disclosure. For example, where an object is rotated 90° and observed, the top and bottom are read as converted to left and right, and where the object is rotated 180° and observed, the top and bottom are read as reversed.

The present disclosure relates to a solid-state imaging device and an electronic device and in particular, to a solid-state imaging device and an electronic device such that are capable of increasing sensitivity and dynamic range on a low-illuminance side without increasing the size of a pixel section when the pixel section is configured of two types of pixels that differ in light-receiving areas.

A method of increasing the size of pixels is used for capturing high-sensitivity images in a solid-state imaging device. However, with this method, where the number of pixels is not changed, the solid-state imaging device is increased in size, which raises the cost of the solid-state imaging device and increases the size of a camera including the solid-state imaging device, thereby imposing restrictions on the installation locations of the camera. Meanwhile, where the size of the solid-state imaging device is not changed, the number of pixels is decreased and the resolution is decreased.

A method of increasing the number of pixels is used for capturing high-resolution images in a solid-state imaging device. However, with this method, where the size of pixels is not changed, the solid-state imaging device is increased in size, which raises the cost of the solid-state imaging device and increases the size of a camera including the solid-state imaging device, thereby imposing restrictions on the installation locations of the camera. Meanwhile, where the size of pixels is reduced, high resolution can be realized while suppressing the increase in size of the solid-state imaging device, but the sensitivity decreases.

There is a solid-state imaging device which has pixels with a large aperture and pixels with a small aperture and in which the adjacent pixels of the two types have a color filter of the same color, red, green, or blue, to increase the dynamic range (see, for example, PTL 1).

### 1. First Embodiment

### <Configuration Example of Imaging Device>

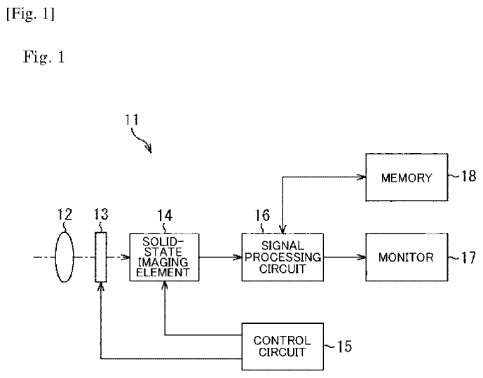

Light detecting devices are described herein. A light detecting device may comprise an imaging device. FIG. 1 is a block diagram showing an exemplary configuration of the first embodiment of an imaging device as an electronic device to which the present art is applied.

An imaging device 11 in FIG. 1 is configured of an optical system 12, a shutter device 13, a solid-state imaging element 14, a control circuit 15, an signal processing circuit 16, a monitor 17, and a memory 18. The imaging device 11 captures an image of an object and displays or records an HDR image, which is a high dynamic range image, as a captured image.

Specifically, the optical system 12 has one or a plurality of lenses, guides light from the object to the solid-state imaging element 14, and forms an image on the light-receiving surface of the solid-state imaging element 14.

The shutter device 13 is arranged between the optical system 12 and the solid-state imaging element 14 and controls a period in which the solid-state imaging element 14 is irradiated with light and a period in which the light is blocked according to the control by the control circuit 15.

The solid-state imaging element 14 is, for example, a CMOS (Complementary Metal Oxide Semiconductor) image sensor. The solid-state imaging element 14 is configured by arranging a plurality of pixel sections composed of a main pixel and a sub-pixel, which differ in a light-receiving area, in a matrix on a semiconductor substrate using silicon (Si). The main pixel has a light-receiving area that is larger than the light-receiving area of the sub-pixel. Where it is not necessary to distinguish between the main pixel and the sub-pixel, these are collectively referred to as “pixels”.

Each pixel has a color filter. Light incident through the optical system 12 and the shutter device 13 is received by each pixel through the color filter. Under control by the control circuit 15, the solid-state imaging element 14 outputs a pixel signal, which is a digital signal corresponding to the light received by each pixel, to the signal processing circuit 16.

The control circuit 15 controls the shutter device 13 and the solid-state imaging element 14.

The signal processing circuit 16 supplies the pixel signals supplied from the solid-state imaging element 14 to the memory 18 to be stored therein. If necessary, the signal processing circuit 16 reads pixel signals stored in the memory 18 and performs demosaicing processing by using the pixel signals to generate sub-pixel signals having components of each color of the color filters of the sub-pixels. The signal processing circuit 16 generates a main pixel signal having components of each color of the color filters of the main pixels with respect to the main pixels in the same manner. The signal processing circuit 16 (generation unit) generates an HDR (High Dynamic Range) image composed of pixels corresponding to each pixel section by using the sub-pixel signals and main pixel signals of each pixel section. The signal processing circuit 16 supplies the HDR image to be displayed as a captured image on the monitor 17, or to be recorded on a recording medium (not shown).

The monitor 17 displays the captured image supplied from the signal processing circuit 16. The memory 18 stores the pixel signal supplied from the signal processing circuit 16.

As described above, each pixel section of the solid-state imaging element 14 is configured of a main pixel and a sub-pixel, which differ in a light-receiving area. Therefore, by generating the captured image by using the pixel signals of the main pixel and sub-pixel constituting each pixel section, the signal processing circuit 16 can expand the dynamic range of the captured image.

### <Exemplary Configuration of CMOS Image Sensor>

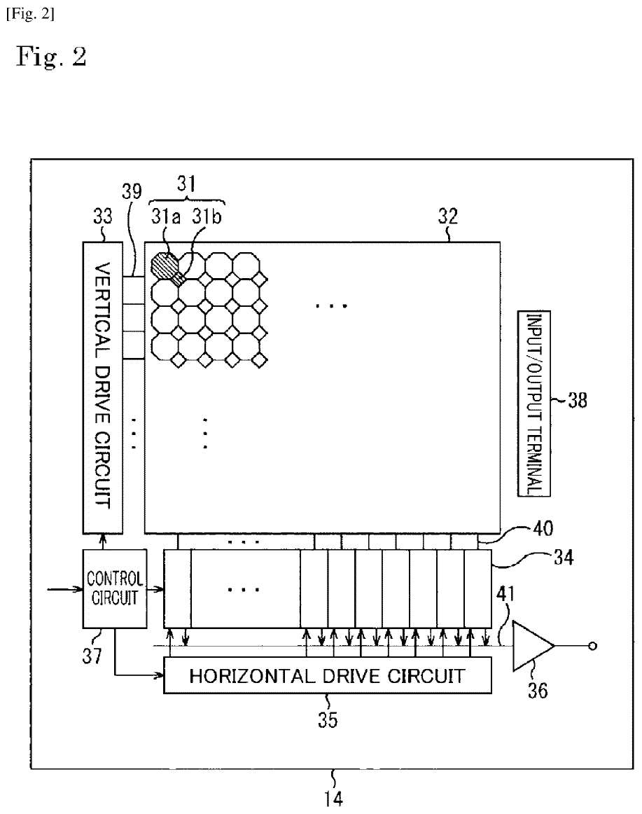

FIG. 2 shows an exemplary circuit configuration of the solid-state imaging element 14 in FIG. 1.

The solid-state imaging element 14 includes a pixel array section 32 in which a plurality of pixel sections 31 is arranged in a matrix, a vertical drive circuit 33, column signal processing circuits 34, a horizontal drive circuit 35, an output circuit 36, a control circuit 37, an input/output terminal 38, and the like.

The pixel section 31 is configured of a main pixel 31a and a sub-pixel 31b. The main pixel 31a and the sub-pixel 31b each have a photodiode as a photoelectric conversion element and a plurality of pixel transistors. The light-receiving area of the photodiode of the main pixel 31a is larger than the light-receiving area of the photodiode of the sub-pixel 31b.

The vertical drive circuit 33 is configured of, for example, a shift register and connected to the pixel sections 31 of each row through a pixel drive wiring 39. The vertical drive circuit 33 selects a predetermined pixel drive wiring 39 according to a clock signal or control signal supplied from the control circuit 37 and supplies a pulse for driving the pixel section 31 to the pixel drive wiring 39, thereby driving the pixel section 31 in row units. Specifically, the vertical drive circuit 33 successively selects and scans the pixel sections 31 of the pixel array section 32 in the vertical direction in row units. As a result, pixel signals based on signal charges generated according to the received quantity of light in the photodiode of each main pixel 31a and each sub-pixel 31b of the pixel sections 31 are output in row units to the column signal processing circuits 34 through separate vertical signal lines 40.

The column signal processing circuit 34 is arranged for each column of pixel sections 31 and is connected to each of the main pixels 31a and sub-pixels 31b of the pixel sections 31 of the column corresponding thereto through the vertical signal line 40. The column signal processing circuit 34 performs signal processing such as noise removal with respect to the pixel signals inputted through the vertical signal line 40 from each of the main pixels 31a and sub-pixels 31b of the pixel sections 31 of the column corresponding thereto according to a clock signal or control signal supplied from the control circuit 37. Examples of such signal processing include CDS (Correlated Double Sampling), AD (Analog Digital) conversion, and the like for removing fixed pattern noise inherent to pixels.

The horizontal drive circuit 35 is configured of, for example, a shift register. The horizontal drive circuit 35 successively outputs horizontal scan pulses to each column signal processing circuit 34 according to a clock signal or control signal supplied from the control circuit 37. As a result, the horizontal drive circuit 35 orderly selects each of the column signal processing circuits 34 and outputs pixel signals of the main pixels 31a and sub-pixels 31b from each of the column signal processing circuits 34 to the respective horizontal signal line 41.

The output circuit 36 performs signal processing with respect to each pixel signal of the main pixels 31a and sub-pixels 31b that are successively supplied from each of the column signal processing circuits 34 through the horizontal signal lines 41 and outputs the processed signals. The output circuit 36 may perform, for example, only buffering or may perform black level adjustment, column spread correction, various types of digital signal processing, and the like. The input/output terminal 38 exchanges signals with the outside.

The control circuit 37 inputs a vertical synchronization signal, a horizontal synchronization signal, a master clock, and the like from the control circuit 15 in FIG. 1. The control circuit 37 generates clock signals and control signals as references for the operation of the vertical drive circuit 33, the column signal processing circuits 34, and the horizontal drive circuit 35 on the basis of the vertical synchronization signal, the horizontal synchronization signal, and the master clock. The control circuit 37 outputs these clock signals and control signals to the vertical drive circuit 33, the column signal processing circuits 34, and the horizontal drive circuit 35.

### <Exemplary First Array of Color Filters>

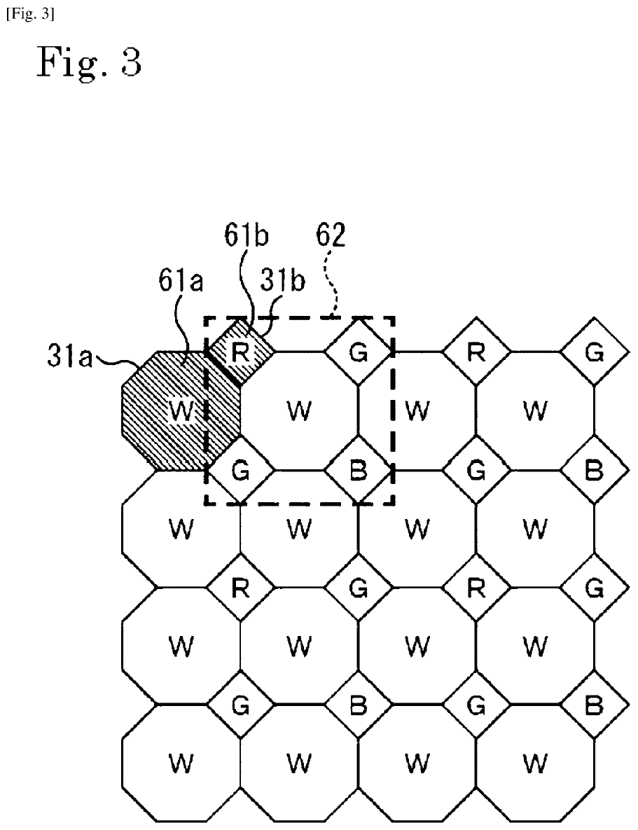

FIG. 3 is a top view showing the exemplary first array of color filters provided in the pixel array section 32 in FIG. 2. FIG. 3 shows one embodiment where more than half of the main pixels in a pixel array may have clear filters, yellow color filters, or no color filters.

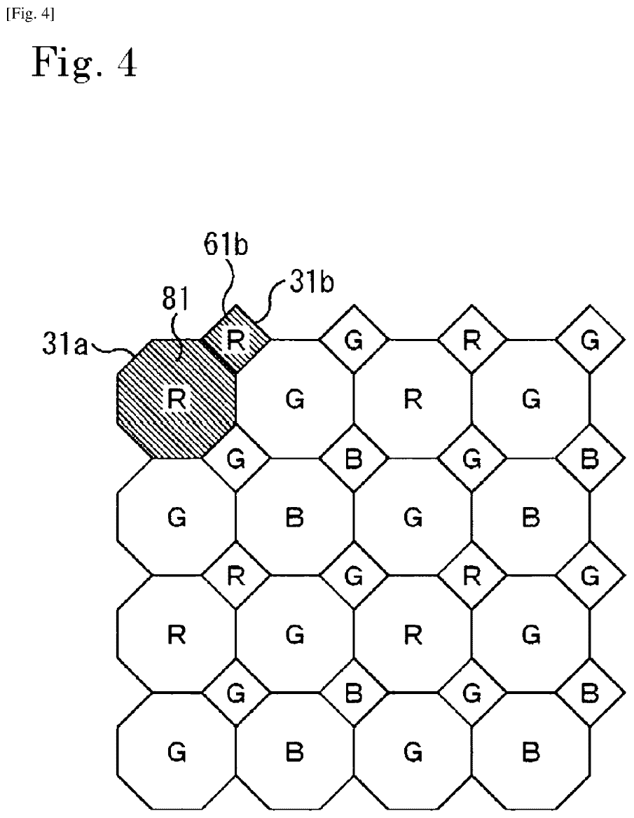

In FIG. 3, only color filters of 4×4 pixel sections 31, which are part of the pixel sections provided in the pixel array section 32, are shown, but the same applies to the color filters of other pixel sections 31. The same is true for FIGS. 4, 5, and 8 described hereinbelow.

In the example in FIG. 3, a color filter 61a of each main pixel 31a has a regular octagonal shape when viewed from above. All color filters 61a of a large color filter group (second color filter group) constituted by the color filters 61a of the main pixels 31a arranged in the pixel array section 32 are white (clear) (W) color filters transmitting light of all visible colors including green color which is a brightness component. In some embodiments, pixels may have no color filter.

A color filter 61b of each sub-pixel 31b has a square shape in contact with the lower right side of the regular octagon of the color filter 61a when viewed from above. The array of a small color filter group (first color filter group) constituted by the color filters 61b of the sub-pixels 31b arranged in the pixel array section 32 is a Bayer array. Specifically, where the small color filter group is successively divided into array units 62 of 2 (row)×2 (column) color filters 61b from the upper left color filter, the color of the upper left color filter 61b within this array unit 62 is red (R). The color of the upper right and lower left color filters 61b is green (G), and the color of the lower right color filter 61b is blue (B). That is, the small color filter group is configured of three types of color filters of red, green, and blue.

### <Effect of Array of Large Color Filter Group>

The effect produced by the array of the large color filter group in FIG. 3 will be explained hereinbelow with reference to FIG. 4.

Where the array of the large color filter group is a Bayer array similarly to the array of the small color filter group as shown in FIG. 4, the light received by the photodiode of the main pixel 31a is only red, green, or blue. Therefore, the dynamic range on the low-illuminance (low-brightness) side is not increased.

By contrast, with the array shown in FIG. 3, all the color filters 61a of the large color filter group are white color filters (in other words, clear filters) that transmit light of all visible colors. Therefore, the light received by the photodiode of the main pixel 31a is the light of all visible colors. Thus, the imaging device 11 can increase the dynamic range on the low-illuminance side and increase the SN (Single/Noise) ratio of brightness on the low-illuminance side. As a result, the visibility of the object for which the image was captured under low illuminance in the HDR image can be improved.

However, since the light received by the photodiode of the main pixel 31a is the light of all visible colors, the main pixel signal has only a white component, that is, does not have color components. Therefore, the color of the object with low illuminance in the HDR image cannot be distinguished. However, since the array of the small color filter group is a Bayer array, the sub-pixel signals have red, green and blue components. Therefore, color reproduction of the high-brightness object in the HDR image can be performed.

The array of the small color filter group may be other than the Bayer array, provided that color reproduction can be performed using sub-pixel signals. Further, the type of colors of the color filters 61b is not limited to three colors of red, green and blue and may be, for example, three colors of yellow, red and cyan.

The color filter 61a is not limited to a white color filter (no-color filter), provided that it is a broadband color filter, which is a color filter transmitting light in a band including the band of light transmitted by a green color filter, that is, light contributing to a brightness value. For example, the color of the color filter 61a may be yellow, green, cyan, and the like. In this case, since the light received by the photodiode of the main pixel 31a contributes to the brightness value, the dynamic range on the low-illuminance side can be also increased.

### <Exemplary Second Array of Color Filters>

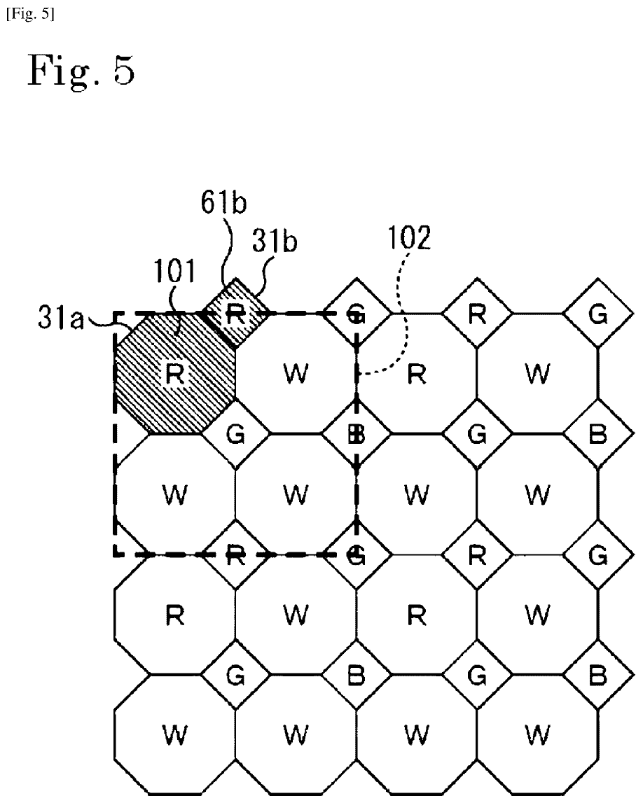

FIG. 5 is a top view showing the exemplary second array of color filters provided in the pixel array section 32. FIG. 5 shows another embodiment where more than half of the main pixels in a pixel array may have clear filters, yellow color filters, or no color filters.

In the exemplary array in FIG. 5, portions corresponding to those of the exemplary array in FIG. 3 are assigned with the same reference numerals. Therefore, the explanation of these portions is omitted, as appropriate, and the explanation is focused on portions different from those in the exemplary array in FIG. 3. The exemplary array in FIG. 5 differs from the exemplary array shown in FIG. 3 in that some of color filters of the large color filter group are red color filters, and is otherwise configured in the same manner as the exemplary array in FIG. 3.

Specifically, where the large color filter group is successively divided into array units 102 of 2 (row)×2 (column) color filters 101 from the upper left color filter, the color of the upper left color filter 101 within this array unit 102 is red (R). The color of other three color filters 101 is white (W).

That is, only some color filters 101 of the large color filter group are white color filters. Further, the ratio of the white color filters 101 in the large color filter group is larger than the ratio of the green color filters 81 in the large color filter group when the array of the large color filter group shown in FIG. 4 is a Bayer array. Specifically, the ratio of the white color filters 101 in the large color filter group shown in FIG. 5 is 75% (¾), which is larger than 50% ( 2/4) which is the ratio of the green color filters 81 in the large color filter group in FIG. 4.

It follows from the above that with the array in FIG. 5, the dynamic range on the low-illuminance side can be increased as compared with the array in FIG. 4 in the same manner as with the array in FIG. 3. Further, with the array in FIG. 5, since the light received by the photodiode of the main pixel 31a having the red color filter 101 is red light, the main pixel signal has a red component. The red color of a low-illuminance object can be distinguished in an HDR image.

In the example shown in FIG. 5, the color of the color filters 101 other than the white color filter 101 is red, but it may be blue or other color. Further, the number of colors of the color filters 101 is not limited to one. For example, one of the upper left color filters 101 of two adjacent array units 102 may be a red color filter and the other may be a blue or cyan color filter.

As described hereinabove, in the solid-state imaging element 14, the ratio of the color filters 61a (101) in the large color filter group is larger than the ratio of the green color filters 81 in the large color filter group in the case where the array of the large color filter group in FIG. 3 is a Bayer array. That is, the large color filter group of the solid-state imaging element 14 is provided with a wider band than the large color filter group in FIG. 3. Therefore, with the solid-state imaging element 14, the dynamic range on the low-illuminance side can be increased without increasing the size of the main pixels 31a. As a result, the imaging device 11 can capture a high-sensitivity HDR image with high resolution without increasing the size.

By contrast, where the array of the large color filter group is a Bayer array as shown in FIG. 3, the main pixels 31a need to be increased in size in order to increase the dynamic range of the low-illuminance side. Therefore, the solid-state imaging element 14 is increased in size, or the number of the main pixels 31a is reduced in order to suppress the increase in size of the solid-state imaging element 14, and the resolution of the HDR image decreases.

### 2. Second Embodiment

### <Exemplary Configuration of Imaging Device>

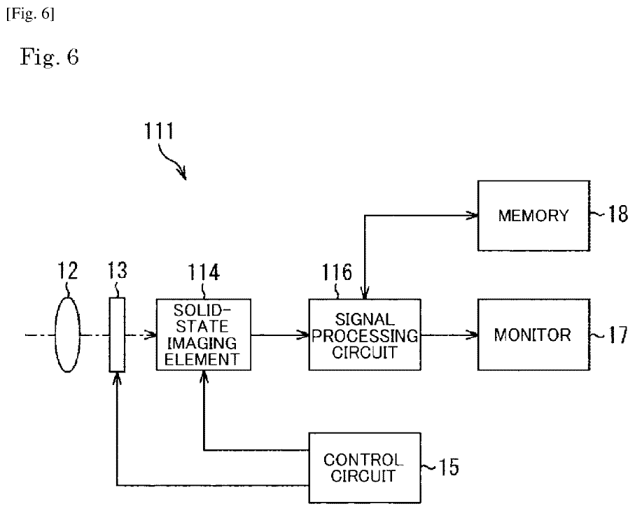

FIG. 6 is a block diagram showing an exemplary configuration of the second embodiment of the imaging device as an electronic device employing the present art.

In an imaging device 111 in FIG. 6, portions corresponding to the imaging device 11 in FIG. 1 are assigned with the same reference numerals. Therefore, the explanation of these portions is omitted, as appropriate, and the explanation is focused on portions different from those in the imaging device 11 in FIG. 1. The imaging device 111 differs from the imaging device 11 in that the array direction of adjacent color filters within the large color filter group is tilted 45 degrees to the right with respect to the row direction and in that pixel interpolation is performed, and is otherwise configured in the same manner as the imaging device 11.

Imaging device 111 may include at least one processor configured to generate image data. The at least one processor may be configured to generate the image data based on signals from pixels of a pixel array included in solid-state imagine device 114. Specifically, the imaging device 111 in FIG. 6 includes a solid-state imaging element 114 and a signal processing circuit 116 instead of the solid-state imaging element 14 and the signal processing circuit 16.

The solid-state imaging element 114 differs from the solid-state imaging element 14 in that the array direction of adjacent color filters within the large color filter group is tilted 45 degrees to the right with respect to the row direction, and is otherwise configured in the same manner as the solid-state imaging element 14.

The signal processing circuit 116 supplies pixel signals supplied from the solid-state imaging element 114 to the memory 18 to be stored therein. If necessary, the signal processing circuit 116 generates sub-pixel signals and main pixel signals while reading the pixel signals stored in the memory 18, in the same manner as the signal processing circuit 16.

The signal processing circuit 116 (generation unit) uses the sub-pixel signals to interpolate sub-pixel signals at an intermediate position between two sub-pixels adjacent in the row direction and column direction, and the interpolated signal may comprise an intermediate sub-pixel signal. The signal processing circuit 116 uses the main pixel signals to interpolate main pixel signals at an intermediate position between two main pixels adjacent in the row direction and column direction, and the interpolated signal may comprise an intermediate main pixel signal. The signal processing circuit 116 uses the interpolated sub-pixel signals and the interpolated main pixel signals to generate an HDR image. The signal processing circuit 116 supplies the HDR image to be displayed as a captured image on the monitor 17, or to be recorded on a recording medium (not shown).

Here, the signal processing circuit 116 generates the HDR image after separately interpolating the sub-pixel signals and the main pixel signals, but the interpolation may be performed after generating the HDR image. In this case, the signal processing circuit 116 generates an HDR image using sub-pixel signals and main pixel signals of each pixel section similarly to the signal processing circuit 16. After that, the signal processing circuit 116 uses the pixel signals of two pixels adjacent in the row direction and column direction of the HDR image to interpolate pixel signals at an intermediate position between the two pixels. Then, the signal processing circuit 116 sets the interpolated HDR image as the captured image.

The configuration of the solid-state imaging element 114 is the same as the configuration of the solid-state imaging element 14 in FIG. 2, except for the configuration of the pixel array section. Therefore, only the pixel array section of the solid-state imaging element 114 will be described below.

### <Exemplary Configuration of Pixel Array Section>

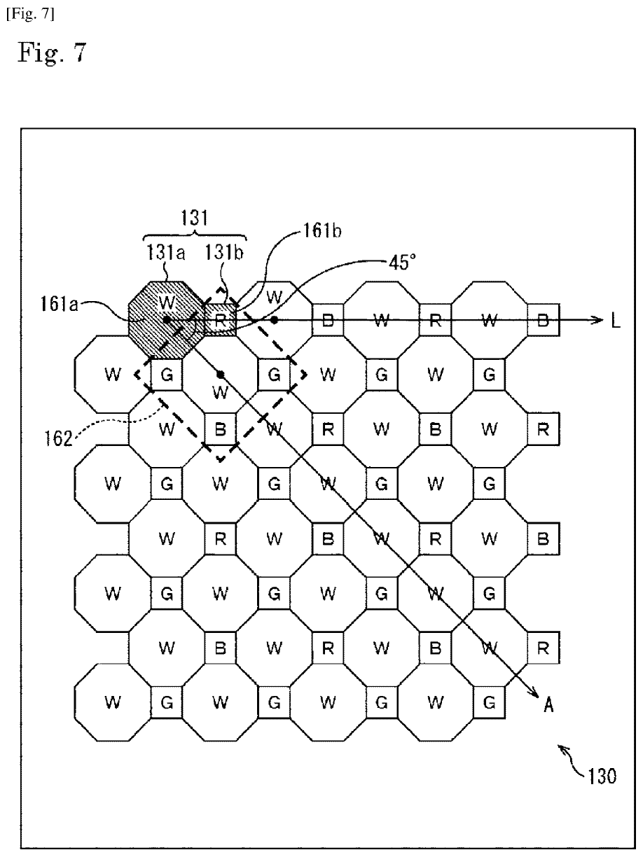

FIG. 7 is a top view showing an exemplary configuration of the pixel array section of the solid-state imaging element 114. FIG. 7 shows another embodiment where more than half of the main pixels in a pixel array may have clear filters, yellow color filters, or no color filters.

The pixel array section 130 of FIG. 7 differs from the pixel array section 32 in that the array direction of adjacent color filters in the large color filter group is tilted 45 degrees to the right with respect to the row direction, and is otherwise configured in the same manner as the pixel array section 32.

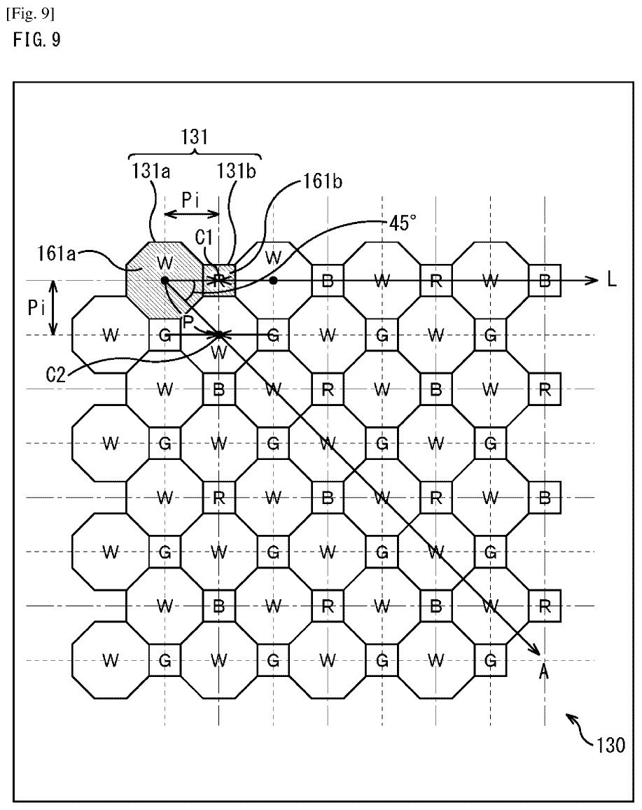

Specifically, in the pixel array section 130 of FIG. 7, a plurality of pixel sections 131 is arranged in a matrix. In FIG. 7, only 4×8 pixel sections 131, which are part of the pixel sections provided in the pixel array section 32, are shown, but the same applies to other pixel sections 131. The same is true for FIGS. 9 to 14 described hereinbelow.

The pixel section 131 is composed of a main pixel 131a and a sub-pixel 131b. A color filter 161a of each main pixel 131a has a regular octagonal shape when viewed from above. All the color filters 161a of the large color filter group are white color filters. The angle between the array direction of adjacent color filters 161a in the large color filter group indicated by arrow A in FIG. 7 and the row direction indicated by arrow L is 45 degrees.

A color filter 161b of each sub-pixel 131b has a square shape in contact with the right central side of the regular octagon of the color filter 161a when viewed from above. The array of the small color filter group is obtained by tilting the Bayer array 45 degrees to the right.

Specifically, where the small color filter group is successively divided into array units 162 of 2 (row)×2 (column) color filters 161b tilted 45 degrees to the right from the upper left color filter, the color of the one color filter 161b of the first row within this array unit 162 is red (R). The two color filters 161b in the second row are both green (G), and the color of the one color filter 161b in the third row is blue (B). That is, the small color filter group is configured of three types of color filters of red, green, and blue.

### <Effect of Color Filter Array>

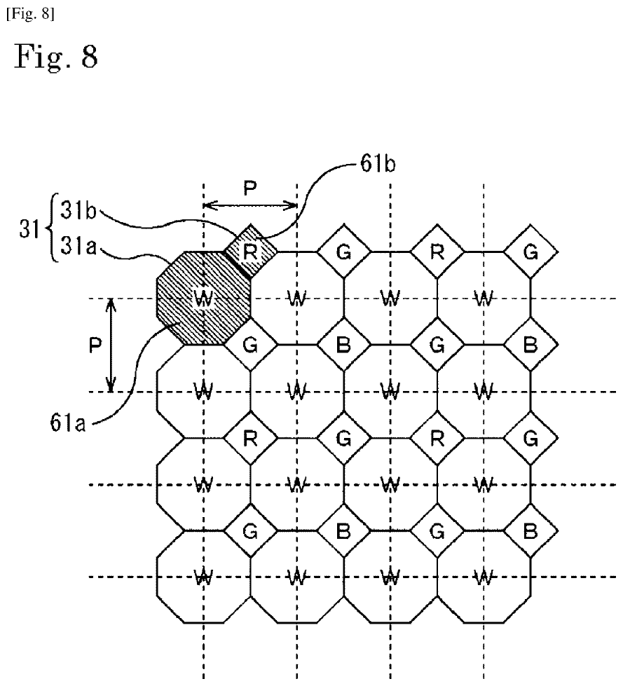

Next, the effect of the array in FIG. 7 will be described with reference to FIGS. 8 to 10.

As shown in FIG. 8, where the interval between the pixel sections 31 is P in both the row direction and the column direction, the interval between the adjacent main pixels 131a arranged side by side in the array direction shown by arrow A in FIG. 9 is P.

As described above, the main pixel signal at the intermediate position between two main pixels 131a adjacent in the row direction and column direction and the sub-pixel signal at the intermediate position between two sub-pixels 131b adjacent in the row direction and column direction are interpolated.

Specifically, for example, the main pixel signal at an intermediate position C1 between two main pixels 131a adjacent in the row direction is interpolated using the main pixel signals of these two main pixels 131a. The sub-pixel signal at an intermediate position C2 between two sub-pixels 131b adjacent in the row direction is interpolated using the sub-pixel signals of these two sub-pixels 131b.

Therefore, an interval Pi in the row direction and column direction between the pixels of the HDR image generated using the interpolated main pixel signals and subpixel signals can be represented by the following Formula (1) by using the interval P between the adjacent main pixels 131a.

$$\begin{matrix}[ Math . 1 ] & \\ Pi = \frac{P}{\sqrt{2}} & ( 1 )\end{matrix}$$

According to Formula (1), Pi is about 1/1.4 of P.

Here, in the imaging device 11, since no interpolation is performed, the interval in the row direction and column direction between the pixels of the HDR image generated by the imaging device 11 is P, which is the interval between the pixel sections 31 in the row direction and column direction. Therefore, the resolution in the row direction and column direction between the pixels of the HDR image generated by the imaging device 111 is about 1.4 times the resolution in the row direction and column direction between the pixels of the HDR image generated by the imaging device 11.

As indicated above, in the imaging device 111, the array direction of the adjacent color filters 161a in the large color filter group is tilted with respect to the row direction, and the main pixel signals and the sub-pixel signals are interpolated in the row direction and column direction. Therefore, compared to the imaging device 11, the resolution of the HDR image can be increased. Also, since the main pixel signal does not have a color component, the interpolation of the main pixel signal does not produce false colors or artifacts.

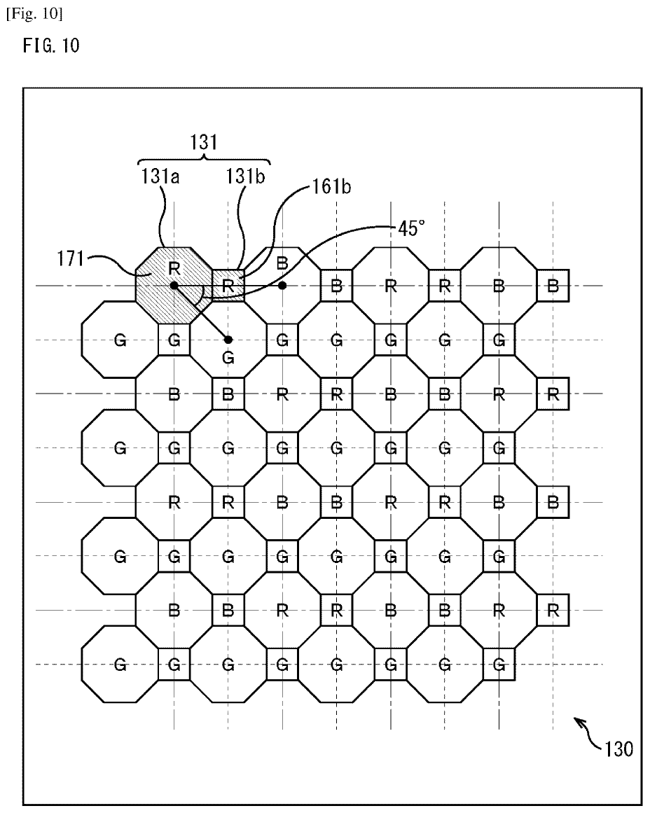

Meanwhile, as shown in FIG. 10, when the array of the large color filter group is obtained by tilting the Bayer array 45 degrees to the right, a color filter 171 of the main pixels 131a of every other row and column shown by dash-dot lines in FIG. 10 is a red or blue color filter. Therefore, when the main pixel signal of the main pixel 131a at the intersection of every other row and column indicated by the dash-dot lines in FIG. 10 is generated, the white balance of the area including that position is calculated, and the green component (brightness information) is calculated. As a consequence, it is difficult to accurately generate the brightness information of the main pixel signals of the chromatic object or the boundary of the chromatic object. As a result, false colors and artifacts may be generated.

The angle of the array direction of adjacent color filters 161a in the large color filter group with respect to the row direction may be other than 45 degrees as long as the angle is greater than 0 degrees and less than 90 degrees.

### <Another Exemplary First Array of Color Filters>

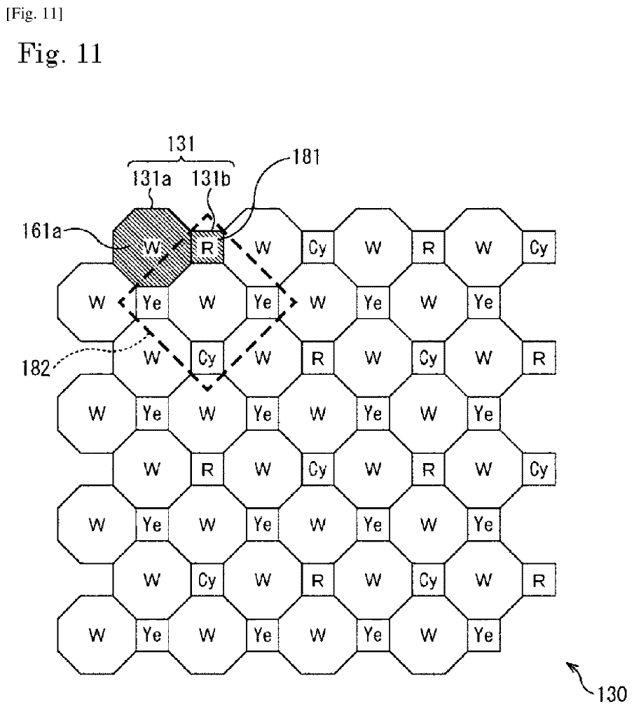

FIG. 11 is a top view showing another exemplary first array of the color filters provided in the pixel array section 130. FIG. 11 shows another embodiment where more than half of the main pixels in a pixel array may have clear filters, yellow color filters, or no color filters.

In the exemplary array in FIG. 11, portions corresponding to those of the exemplary array in FIG. 7 are assigned with the same reference numerals. Therefore, the explanation of these portions is omitted, as appropriate, and the explanation is focused on portions different from those in the exemplary array in FIG. 7. The exemplary array in FIG. 11 differs from the exemplary array in FIG. 7 in that the array of the small color filter group is not the Bayer array, and is otherwise configured in the same manner as the exemplary array in FIG. 7.

Specifically, in the array of the small color filter group, green of the Bayer array in FIG. 7 is replaced with yellow (Ye) and blue is replaced with cyan (Cy). More specifically, where the small color filter group is successively divided into array units 182 of 2 (row)×2 (column) color filters 181 tilted 45 degrees to the right from the upper left color filter, the color of one color filter 181 in the first row within the array unit 182 is red (R). Colors of two color filters 181 in the second row are both yellow (Ye), and the color of one color filter 181 in the third row is cyan (Cy). That is, the small color filter group is configured of three types of color filters of red, yellow, and cyan.

As described above, in the exemplary array of FIG. 11, the small color filter group includes the yellow or cyan color filter 181, which is a broadband color filter. Therefore, the sensitivity of the sub-pixel 131b having this color filter 181 is improved. In addition, as compared with the case of FIG. 7, the occurrence of false colors and artifacts caused by interpolation of sub-pixel signals can be suppressed.

By contrast, in the exemplary array of FIG. 7, the color filters 161b of the sub-pixels 131b of every other row and column indicated by dash-dot lines in FIG. 9 are red or blue color filters. Therefore, when the sub-pixel signal of the sub-pixel 131b at the intersection of every other row and column indicated by the dash-dot lines in FIG. 9 is generated, the white balance of the area including that position is calculated, and the green component (brightness information) is calculated. As a consequence, it is difficult to accurately generate the brightness information of the sub-pixel signals of the chromatic object or the boundary of the chromatic object. As a result, false colors and artifacts may be generated.

In the case where some of the color filters 161b of the sub-pixels 131b in every other row and column indicated by the dash-dot lines in FIG. 9 are made broadband color filters to suppress the occurrence of false color, the number of red and blue color filters in the small color filter group is reduced. Therefore, the color resolution on the high-brightness side of the HDR image is reduced.

### <Another Exemplary Second Array of Color Filters>

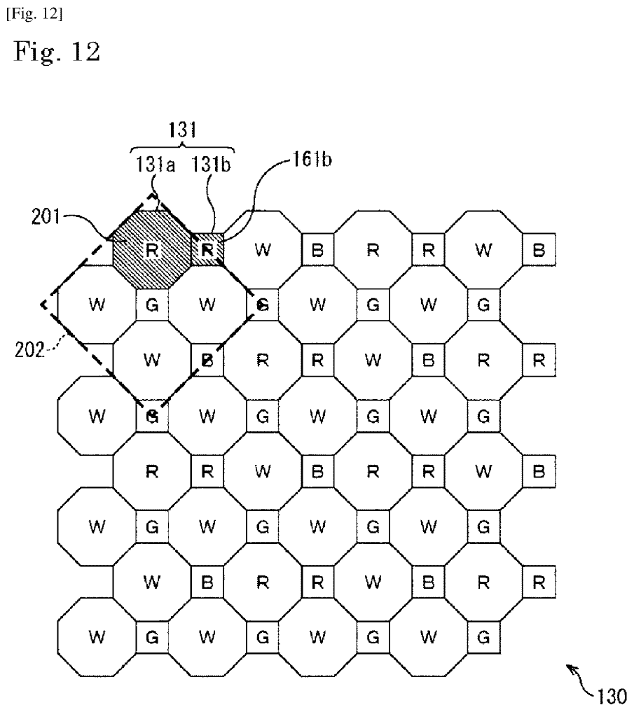

FIG. 12 is a top view showing another exemplary second array of the color filters provided in the pixel array section 130. FIG. 12 shows another embodiment where more than half of the main pixels in a pixel array may have clear filters, yellow color filters, or no color filters.

In the exemplary array in FIG. 12, portions corresponding to those of the exemplary array in FIG. 7 are assigned with the same reference numerals. Therefore, the explanation of these portions is omitted, as appropriate, and the explanation is focused on portions different from those in the exemplary array in FIG. 7. The exemplary array in FIG. 12 differs from the exemplary array in FIG. 7 in that some color filters of the large color filter groups are red color filters, and is otherwise configured in the same manner as the exemplary array in FIG. 7.

Specifically, where the large color filter group is successively divided into array units 202 of 2 (row)×2 (column) color filters 201 tilted 45 degrees to the right from the upper left color filter, the color of one color filter 201 in the first row within the array unit 202 is red (R). The color of the other three color filters 201 is white (W).

That is, only some of the color filters 201 of the large color filter group are white color filters. Also, the ratio of the white color filters 201 in the large color filter group is higher than the ratio of the green color filters 171 in the large color filter group when the array of the large color filter group shown in FIG. 10 is the Bayer array.

Specifically, the ratio of the white color filters 201 in the large color filter group in FIG. 12 is 75% (=¾), and the ratio of the green color filters 171 in the large color filter group in FIG. 10 is greater than 50% (= 2/4).

As described above, with the array in FIG. 12, the dynamic range on the low-illuminance side can be increased as compared to the array in FIG. 10, as with the array in FIG. 7. In addition, with the array in FIG. 12, the light received by the photodiodes of the main pixels 131a having the red color filter 201 is red, so that the red color of low-illuminance object can be distinguished in the HDR image, as with the array in FIG. 5.

In the example in FIG. 12, the color of the color filters 201 is red, but other colors such as blue may be also used.

### <Another Exemplary Third Array of Color Filters>

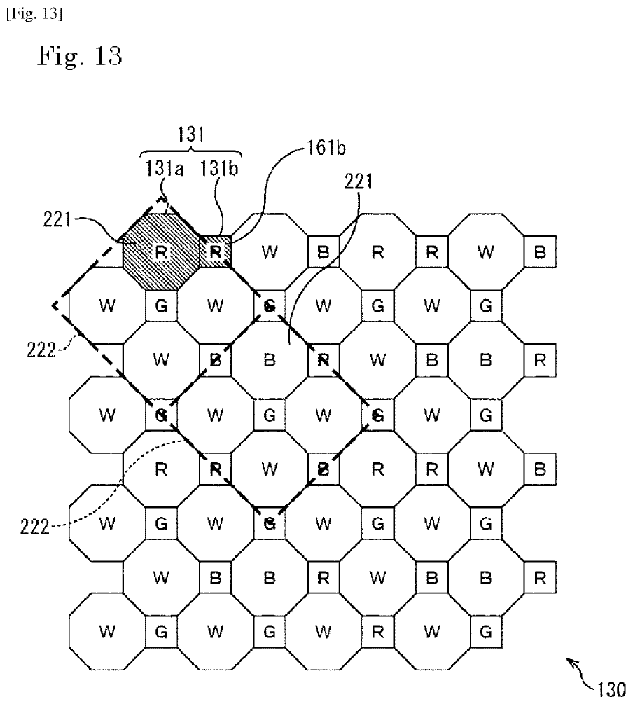

FIG. 13 is a top view showing another exemplary third array of the color filters provided in the pixel array section 130. FIG. 13 shows another embodiment where more than half of the main pixels in a pixel array may have clear filters, yellow color filters, or no color filters.

In the exemplary array in FIG. 13, portions corresponding to those of the exemplary array in FIG. 12 are assigned with the same reference numerals. Therefore, the explanation of these portions is omitted, as appropriate, and the explanation is focused on portions different from those in the exemplary array in FIG. 12. The exemplary array in FIG. 13 differs from the exemplary array in FIG. 12 in that some color filters of the large color filter groups are red or blue color filters, and is otherwise configured in the same manner as the exemplary array in FIG. 12.

Specifically, where the large color filter group is successively divided into array units 222 of 2 (row)×2 (column) color filters 221 tilted 45 degrees to the right from the upper left color filter, the color of the upper left color filter 221 of one of the two adjacent array units 222 is red (R). The color of the other three color filters 221 is white (W). The color of the upper left color filter 221 of the other adjacent array unit is blue (B), and the color of the other three color filters 221 is white (W). That is, the large color filter group is composed of three types of color filters of white, red, and blue.

As described above, the ratio of the white color filters 221 in the large color filter group is the same as in the array in FIG. 12. Therefore, with the array in FIG. 13, the dynamic range on the low illuminance side can be improved as with the array in FIG. 12. In addition, with the array in FIG. 13, since the large color filter group is composed of three types of color filters of white, red, and blue, the main pixel signal has these three types of color components. Therefore, it is possible to reproduce the color of a low-illuminance object in an HDR image.

The colors of the upper left color filters 221 of the adjacent array units 222 are not limited to red and blue, and may be, for example, red and cyan.

### <Another Exemplary Fourth Array of Color Filters>

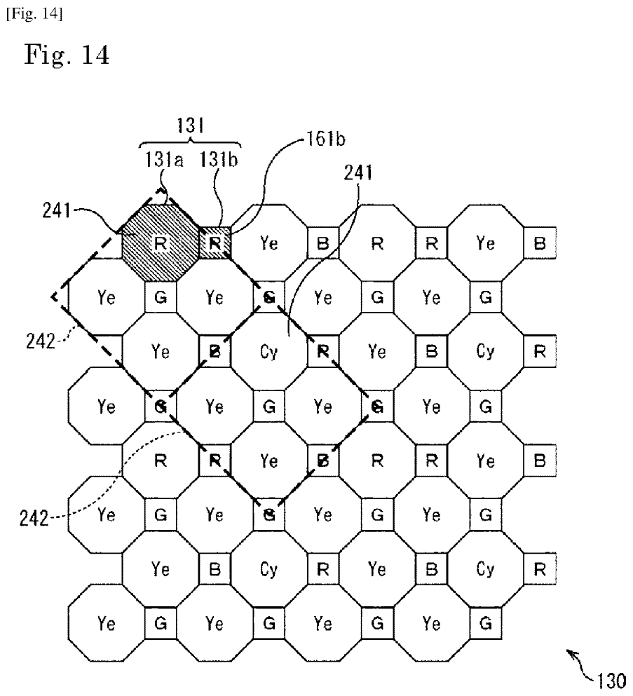

FIG. 14 is a top view showing another exemplary fourth array of the color filters provided in the pixel array section 130. FIG. 14 shows another embodiment where more than half of the main pixels in a pixel array may have clear filters, yellow color filters, or no color filters.

In the exemplary array in FIG. 14, portions corresponding to those of the exemplary array in FIG. 13 are assigned with the same reference numerals. Therefore, the explanation of these portions is omitted, as appropriate, and the explanation is focused on portions different from those in the exemplary array in FIG. 13. The exemplary array in FIG. 14 differs from the exemplary array in FIG. 13 in that the white color filters of the large color filter group are replaced with yellow color filters, and the blue color filters are replaced with cyan color filters, and is otherwise configured in the same manner as the exemplary array in FIG. 13.

Specifically, where the large color filter group is successively divided into array units 242 of 2 (row)×2 (column) color filters 241 tilted 45 degrees to the right from the upper left color filter, the color of one upper left color filter 241 of the two adjacent array units 242 is red (R). The color of the other three color filters 241 is yellow (Ye). The color of the other upper left color filter 241 is cyan (Cy), and the color of the other three color filters 241 is yellow (Ye). That is, the large color filter group is composed of three types of color filters of yellow, red, and cyan.

As described above, the ratio of the yellow and cyan color filters 241, which are broadband color filters, in the large color filter group is larger than the ratio of the green color filters 171 in the large color filter group in the case in which the array of the large color filter group shown in FIG. 10 is the Bayer array. Specifically, the ratio of the color filters 201, which are broadband color filters, in the large color filter group in FIG. 12 is 87.5% (=⅞), which is larger than 50% (=½), which is the ratio of the green color filters 171 in the large color filter group in FIG. 10.

Therefore, with the array in FIG. 14, the dynamic range on the low-illuminance side can be improved compared to the array in FIG. 10 as with the array in FIG. 12. In addition, with the array in FIG. 14, since the large color filter group is composed of three types of color filters of yellow, red, and cyan, the main pixel signal has these three types of color components. Therefore, it is possible to reproduce the color of a low-illuminance object in an HDR image. Since this color reproduction requires division, the SN ratio of colors on the low-illuminance side may deteriorate compared to the array in FIG. 10.

The color filters 161a (201, 221, 241) of the main pixels 131a are not limited to white or yellow color filters, but may be green, cyan, or other color filters as long as they are broadband color filters.

As described above, in the solid-state imaging element 114, the ratio of the color filters 161a (201, 221, 241), which are broadband color filters, in the large color filter group is larger than the ratio of the green color filters 171 in the large color filter group in FIG. 10. Therefore, like the imaging device 11, the imaging device 111 can capture HDR images with high resolution and high sensitivity without increase in size.

In addition, in the solid-state imaging element 114, the angle between the array direction of the adjacent color filters 161a (201, 221, 241) in the large color filter group and the row direction is 45 degrees, which is greater than 0 degrees and less than 90 degrees. Therefore, the solid-state imaging element 114 can improve the resolution in the row direction (horizontal direction) and column direction (vertical direction) of the captured image by pixel interpolation as compared to the solid-state imaging element 14.

In the solid-state imaging element 114, at least one color filter 161a (201, 221, 241) of the two main pixels 131a adjacent in the row direction and at least one color filter of the two main pixels 131a adjacent in the column direction are broadband color filters. Therefore, it is possible to prevent the occurrence of false colors and artifacts caused by interpolation of main pixel signals.

In the first and second embodiments described hereinabove, an HDR image is generated and output using the main pixel signals and the sub-pixel signals, but the main pixel signals and the sub-pixel signals may be output as they are.

The present art can be applied, for example, not only to imaging devices such as digital still cameras and digital video cameras, but also to various electronic devices such as mobile phones with imaging functions and other devices with imaging functions.

### <3. Example of Application to Moving Object>

The art according to the present disclosure (the present art) can be applied to various products. For example, the art according to the present disclosure can be implemented as a device mounted on any type of moving object such as a car, an electric vehicle, a hybrid electric vehicle, a motorcycle, a bicycle, a personal mobility, an airplane, a drone, a ship, a robot, and the like.

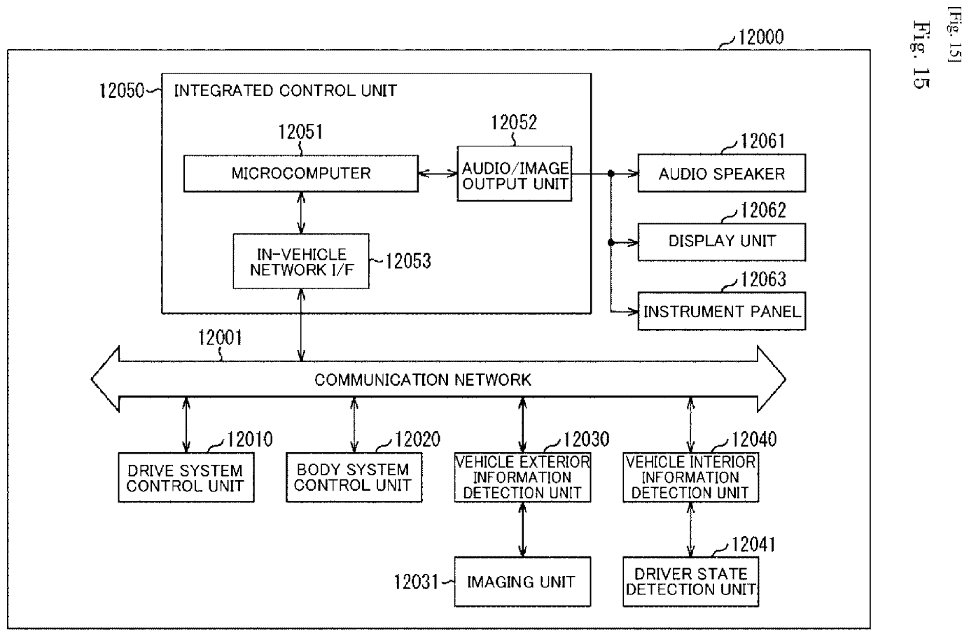

FIG. 15 is a block diagram showing a schematic exemplary configuration of a vehicle control system that is an example of a moving object control system to which the art according to the present disclosure can be applied. Vehicle control systems described herein may be configured to control a vehicle based on image data generated using light detecting devices described herein.

A vehicle control system 12000 includes a plurality of electronic control units connected via a communication network 12001. In the example shown in FIG. 15, the vehicle control system 12000 includes a drive system control unit 12010, a body system control unit 12020, a vehicle exterior information detection unit 12030, a vehicle interior information detection unit 12040, and an integrated control unit 12050. Additionally, a microcomputer 12051, an audio/image output unit 12052, and an in-vehicle network I/F (interface) 12053 are shown as functional components of the integrated control unit 12050.

The drive system control unit 12010 controls the operation of devices related to the drive system of the vehicle in accordance with various kinds of programs. For example, the drive system control unit 12010 functions as a control device for a drive force generation device for generating a drive force of the vehicle, such as an internal combustion engine or a drive motor, a drive force transmission mechanism for transmitting the drive force to wheels, a steering mechanism that adjusts a steering angle of the vehicle, and a brake device that generates the braking force of the vehicle, and the like.

The body system control unit 12020 controls operation of various kinds of devices mounted on the vehicle body in accordance with various kinds of programs. For example, the body system control unit 12020 functions as a keyless entry system, a smart key system, a power window device, or a control device for various lamps such as a head lamp, a back lamp, a brake lamp, a turn indicator, or a fog lamp. In this case, the body system control unit 12020 can receive radio waves transmitted from a portable device that substitutes for a key or signals from various kinds of switches. The body system control unit 12020 receives input of these radio waves or signals and controls a door lock device, a power window device, a lamps, and the like of the vehicle.

The vehicle exterior information detection unit 12030 detects information outside the vehicle on which the vehicle control system 12000 is mounted. For example, an imaging unit 12031 is connected to the vehicle exterior information detection unit 12030. The vehicle exterior information detection unit 12030 causes the imaging unit 12031 to capture an image of the outside of the vehicle, and receives the captured image. The vehicle exterior information detection unit 12030 may perform object detection processing or distance detection processing relative to a person, a vehicle, an obstacle, a sign, a character on a road surface, or the like, on the basis of the received image.

The imaging unit 12031 is an optical sensor that receives light and outputs an electric signal corresponding to the received light quantity. The imaging unit 12031 can output the electric signal as an image or output the electric signal as ranging information. Additionally, the light received by the imaging unit 12031 may be visible light or nonvisible light such as infrared rays.

The vehicle interior information detection unit 12040 detects information inside the vehicle. For example, a driver state detection unit 12041 that detects the state of the driver is connected to the vehicle interior information detection unit 12040. The driver state detection unit 12041 includes, for example, a camera that captures an image of the driver, and the vehicle interior information detection unit 12040 may calculate a degree of fatigue or a degree of concentration of the driver on the basis of the detection information input from the driver state detection unit 12041, or may determine whether the driver is dozing off.

A microcomputer 12051 calculates control target values for the drive force generation device, steering mechanism, or braking device on the basis of information related to the inside and outside of the vehicle acquired by the vehicle exterior information detection unit 12030 or the vehicle interior information detection unit 12040, and can output a control command to the drive system control unit 12010. For example, the microcomputer 12051 can perform cooperative control for the purpose of implementing functions of an ADAS (Advanced Driver Assistance System) including vehicle collision avoidance or impact mitigation, follow-up cruise based on inter-vehicle distance, constant speed cruising, vehicle collision warning, vehicle lane departure warning, or the like.

The microcomputer 12051 can also perform cooperative control for the purpose of automated driving or the like in which the vehicle runs automatedly without relying on the operation by a driver by controlling the drive force generation device, steering mechanism, braking device, or the like on the basis of information related to surroundings of the vehicle acquired by the vehicle exterior information detection unit 12030 or the vehicle interior information detection unit 12040.

Further, the microcomputer 12051 can also output a control command to the body system control unit 12020 on the basis of the vehicle exterior information acquired by the vehicle exterior information detection unit 12030. For example, the microcomputer 12051 controls a headlamp in accordance with a position of a preceding vehicle or an oncoming vehicle detected by the vehicle exterior information detection unit 12030, and performs cooperative control for the purpose of realizing an anti-dazzle function such as switching a high beam to a low beam.

The audio/image output unit 12052 transmits an audio and/or image output signals to an output device capable of visually or audibly notifying information to an occupant of the vehicle or to the vehicle exterior. In the example of FIG. 15, an audio speaker 12061, a display unit 12062, and an instrument panel 12063 are illustrated as output devices. The display unit 12062 may include at least one of an on-board display and a head-up display, for example.

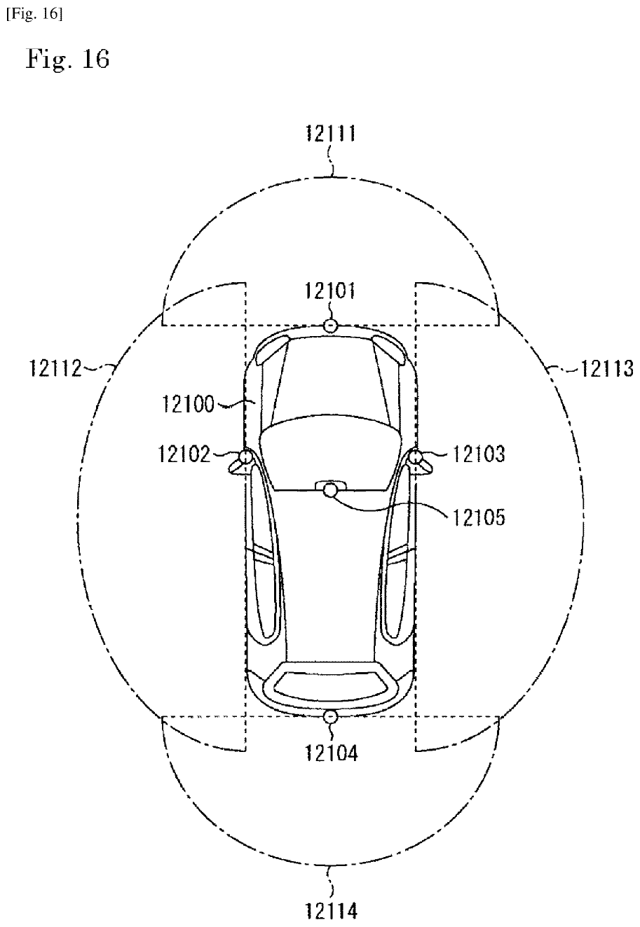

FIG. 16 is a diagram illustrating an exemplary installation position of the imaging unit 12031.

In FIG. 16, a vehicle 12100 has imaging units 12101, 12102, 12103, 12104, and 12105 as the imaging unit 12031.

For example, the imaging units 12101, 12102, 12103, 12104, and 12105 are provided at positions such as a front nose, a side mirror, a rear bumper, a back door, and an upper portion of a front windshield in a passenger compartment of the vehicle 12100. The imaging unit 12101 provided at the front nose and the imaging unit 12105 provided at the upper portion of the front windshield in the passenger compartment mainly acquire images ahead of the vehicle 12100. The imaging units 12102 and 12103 provided at the side mirrors mainly acquire side images of the vehicle 12100. The imaging unit 12104 provided at the rear bumper or the back door mainly acquires images behind the vehicle 12100. The images ahead of the vehicle that are acquired by the imaging units 12101 and 12105 are mainly used for detecting a preceding vehicle, a pedestrian, an obstacle, a traffic signal, a traffic sign, a lane, or the like.

FIG. 16 illustrates exemplary image capturing ranges of the imaging units 12101 to 12104. An imaging range 12111 indicates an imaging range of the imaging unit 12101 provided at the front nose, imaging ranges 12112 and 12113 indicate imaging ranges of the imaging units 12102 and 12103 provided at the respective side mirrors, and an imaging range 12114 indicates an imaging range of the imaging unit 12104 provided at the rear bumper or the back door. For example, an overhead view image of the vehicle 12100 viewed from above can be obtained by superimposing the image data captured by the imaging units 12101 to 12104.

At least one of the imaging units 12101 to 12104 may have a function of acquiring distance information. For example, at least one of the imaging units 12101 to 12104 may be a stereo camera composed of a plurality of imaging elements, or may be an imaging element having pixels for phase difference detection.

For example, based on the distance information obtained from the imaging units 12101 to 12104, the microcomputer 12051 can obtain a distance to each three-dimensional object within the imaging ranges 12111 to 12114 and temporal change of the distance (speed relative to the vehicle 12100), thereby extracting, as a preceding vehicle, a three-dimensional object traveling in substantially the same direction as the vehicle 12100 at a predetermined speed (for example, 0 km/h or more), in particular, the closest three-dimensional object present on a traveling route of the vehicle 12100. Furthermore, the microcomputer 12051 can preliminarily set an inter-vehicle distance to be ensured in a space ahead with a preceding vehicle, and can perform automatic brake control (including follow-up cruising stop control), automatic acceleration control (including follow-up cruising start control), or the like. In this way, cooperative control can be performed for the purpose of automated driving or the like in which the vehicle runs automatedly without relying on operation of a driver.

For example, the microcomputer 12051 can categorize three-dimensional object data related to a three-dimensional object into three-dimensional objects such as a two-wheeled vehicle, a regular vehicle, a large vehicle, a pedestrian, a telephone pole, and the like on the basis of distance information obtained from the imaging units 12101 to 12104 extract the categorized objects, and use the same to automatically avoid obstacles. For example, the microcomputer 12051 distinguishes obstacles around vehicle 12100 into those that can be visible and those that can be hardly visible by the driver of the vehicle 12100. Then, the microcomputer 12051 determines a collision risk indicating a risk level of collision with each of the obstacles, and when the collision risk is a set value or higher and collision may occur, the microcomputer can provide operation assistance in order to avoid collision by outputting an alarm to the driver via the audio speaker 12061 and the display unit 12062, or by performing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether the pedestrian is present in the image captured by the imaging unit 12101 to 12104. Such recognition for a pedestrian is performed by, for example, a procedure for extracting feature points from images captured by the imaging units 12101 to 12104 functioning as infrared cameras, and a procedure for performing pattern matching processing on a series of feature points indicating the outline of an object. Where the microcomputer 12051 determines that a pedestrian is present in the captured images of the imaging units 12101 to 12104 and recognizes the pedestrian, the audio/image output unit 12052 controls the display unit 12062 so as to display a rectangular contour line superimposed on the recognized pedestrian for emphasis. Furthermore, the audio/image output unit 12052 may control the display unit 12062 so as to display an icon or the like indicating the pedestrian at a desired position.

The exemplary vehicle control system to which the art according to the present disclosure can be applied has been described above. The art according to the present disclosure can be applied to the imaging unit 12031 among the components described above. Specifically, the imaging device 11 in FIG. 1 and the imaging device 111 in FIG. 6 can be applied to the imaging unit 12031. By applying the art according to the present disclosure to the imaging unit 12031, it is possible to increase sensitivity and dynamic range on a low-illuminance side without increasing the size of a pixel section when the pixel section is configured of two types of pixels that differ in light-receiving areas. As a result, in the vehicle control system 12000, a compact imaging unit 12031 that captures HDR images with high resolution and high sensitivity can be realized.

In this case, the color of low-illuminance objects with cannot be reproduced in the captured image, or the color reproducibility is low. However, in the vehicle control system 12000 used in automated driving, a driving support system, or the like, the objects that require color recognition are high-brightness objects such as light sources of traffic lights and brake lights, and color reproducibility of low-illuminance objects is not a big problem compared to color reproducibility of high-brightness subjects.

The embodiments of the present art are not limited to the above-described embodiments, and various modifications are possible without departing from the gist of the present art.

For example, all or some of the above-described multiple embodiments can be combined together.

The effects described in the present description are only exemplary and are not limiting, and there may be effects other than those described in the present description.

The present art can take the following configurations.

(1)

A solid-state imaging device including:
a pixel array in which a plurality of pixel sections, each configured of a sub-pixel having a first light-receiving area and a main pixel having a second light-receiving area that is larger than the first light-receiving area, is arranged in a matrix, wherein
a first color filter group configured of color filters of each of the plurality of subpixels arranged in the pixel array is configured of three types of color filters;
at least some filters of a second color filter group configured of color filters of each of the plurality of main pixels arranged in the pixel array are broadband color filters that transmit light in a band including a green light band; and
the ratio of the broadband color filters in the second color filter group is more than 50 percent.
   (2)

The solid-state imaging device according to (1) hereinabove, wherein the broadband color filters are color filters that transmit light of all visible colors.

(3)

The solid-state imaging device according to (1) hereinabove, wherein the broadband color filters are yellow or green color filters.

(4)

The solid-state imaging device according to any one of (1) to (3) hereinabove, wherein all color filters of the second color filter group are the broadband color filters.

(5)

The solid-state imaging device according to any one of (1) to (3) hereinabove, wherein the second color filter group is configured of the broadband color filters and red or blue color filters.

(6)

The solid-state imaging device according to any one of (1) to (3) hereinabove, wherein the second color filter group is configured of the broadband color filters, red color filters, and blue color filters.

(7)

The solid-state imaging device according to any one of (1) to (3) hereinabove, wherein the second color filter group is configured of the broadband color filters, cyan color filters, and red color filters.

(8)

The solid-state imaging device according to any one of (1) to (7) hereinabove, wherein an angle between an array direction of the adjacent color filters in the second color filter group and a row direction is larger than 0 degrees and smaller than 90 degrees.

(9)

The solid-state imaging device according to (8) hereinabove, wherein the three types of color filters are red, yellow and cyan color filters.

(10)

An electronic device comprising:
a solid-state imaging device configured to include:
a pixel array in which a plurality of pixel sections, each configured of a sub-pixel having a first light-receiving area and a main pixel having a second light-receiving area that is larger than the first light-receiving area, is arranged in a matrix,
a first color filter group configured of color filters of each of the plurality of sub-pixels arranged in the pixel array being configured of three types of color filters,
at least some filters of a second color filter group configured of color filters of each of the plurality of main pixels arranged in the pixel array being broadband color filters, which are color filters that transmit light in a band including a green light band, and the ratio of the broadband color filters in the second color filter group being more than 50 percent; and
a generation unit that generates an image by using sub-pixel signals, which are pixel signals corresponding to light received by the sub-pixels, and main pixel signals, which are pixel signals corresponding to light received by the main pixels.
   (11)

The electronic device according to (10) hereinabove, wherein
an angle between an array direction of the adjacent color filters in the second color filter group and a row direction is larger than 0 degrees and smaller than 90 degrees, and
the generation unit uses the sub-pixel signals to perform interpolation of sub-pixel signals at positions between the sub-pixels adjacent in a row direction and a column direction, uses the main pixel signals to perform interpolation of main pixel signals at positions between the main pixels adjacent in a row direction and a column direction, and uses the interpolated sub-pixel signals and main pixel signals to generate the image.

### (A1)

A light detecting device, comprising:
a pixel array comprising:
a plurality of main pixels; and
a plurality of sub-pixels having color filters,
wherein more than half of the plurality of main pixels have clear filters, yellow color filters, or no color filters.

### (A2)

The light detecting device of (A1), wherein the plurality of sub-pixels comprises:
a first group of sub-pixels having color filters of a first color;
a second group of sub-pixels having color filters of a second color; and
a third group of sub-pixels having color filters of a third color.

### (A3)

The light detecting device of (A2), wherein the color filter of the first color comprises
a red color filter.

### (A4)

The light detecting device of (A3), wherein:
the color filter of the second color comprises a blue color filter; and
the color filter of the third color comprises a green color filter.

### (A5)

The light detecting device of any one of (A2) to (A4), wherein:
the color filter of the first color comprises a red color filter;
the color filter of the second color comprises a yellow color filter; and
the color filter of the third color comprises a cyan color filter.

### (A6)

The light detecting device of any one of (A1) to (A5), wherein a light receiving area of each main pixel of the plurality of main pixels comprises an octagonal shape.

### (A7)

The light detecting device of any one of (A1) to (A6), wherein each main pixel of the plurality of main pixels has a clear filter or no color filter.

### (A8)

The light detecting device of any one of (A1) to (A7), wherein at least one main pixel of the plurality of main pixels has a red color filter.

### (A9)

The light detecting device of any one of (A1) to (A8), further comprising:
a column signal line extending in a column direction;
a pixel control signal line extending in a horizontal direction,
wherein the plurality of main pixels and the plurality of sub-pixels are arranged in a plurality of pixel columns in the column direction and a plurality of pixel rows in the horizontal direction.

### (A10)

The light detecting device of (A9), wherein at least one main pixel of the plurality of main pixels has a red color filter.

### (A11)

The light detecting device of (A9), wherein:
at least one main pixel of the plurality of main pixels has a red color filter; and
at least one main pixel of the plurality of main pixels has a blue color filter.

### (A12)

The light detecting device of (A9), wherein each pixel row of the plurality of pixel rows includes at least one pixel having a clear filter or no color filter.

### (A13)

The light detecting device of (A12), wherein each pixel column of the plurality of pixel columns includes at least one pixel having a clear filter or no color filter.

### (A14)

The light detecting device any one of (A1) to (A13), wherein:
more than half of the plurality of main pixels have yellow color filters;
at least one main pixel of the plurality of main pixels has a red color filter; and
at least one main pixel of the plurality of main pixels has a cyan color filter.

### (A15)

The light detecting device of any one of (A1) to (A14), further comprising a processor configured to generate image data based on signals from the plurality of main pixels and signals from the plurality of sub-pixels.

### (A16)

The light detecting device of (A15), wherein:
the processor is configured to calculate using interpolation:
intermediate main pixel signals for positions between main pixels of the plurality of main pixels; and
intermediate sub-pixel signals for positions between sub-pixels of the plurality of subpixels; and
the processor is configured to generate the image data based on signals from the plurality of main pixels, signals from the plurality of sub-pixels, the intermediate main pixel signals, and the intermediate sub-pixel signals.

### (A17)

A vehicle, comprising:
a light detecting device configured to generate signals;
a processor configured to generate image data based on the signals from the light detecting device;
a vehicle control system configured to control the vehicle based on the image data,
wherein the light detecting device comprises:
a pixel array comprising:
a plurality of main pixels; and
a plurality of sub-pixels having color filters,
wherein more than half of the plurality of main pixels have clear filters, yellow color filters, or no color filters.

### (A18)

An automotive camera system comprising:
a lens,
a light detecting device, comprising:
a pixel array comprising:
a plurality of main pixels; and
a plurality of sub-pixels having color filters,
wherein more than half of the plurality of main pixels have clear filters, yellow color filters, or no color filters; and
a processor configured to generate image data based on signals from the plurality of main pixels and signals from the plurality of sub-pixels.

### (A19)

The automotive camera system of (A18), wherein at least one main pixel of the plurality of main pixels has a red color filter.

### (A20)

The automotive camera system of (A18) or (A19), wherein:
the processor is configured to calculate using interpolation:
intermediate main pixel signals for positions between main pixels of the plurality of main pixels; and
intermediate sub-pixel signals for positions between sub-pixels of the plurality of subpixels; and
the processor is configured to generate the image data based on signals from the plurality of main pixels, signals from the plurality of sub-pixels, the intermediate main pixel signals, and the intermediate sub-pixel signals.

### REFERENCE SIGNS LIST

11 Imaging device
14 Solid-state imaging element
16 Signal processing circuit
31 Pixel section
31a Main pixel
31b Sub-pixel
32 Pixel array section
61a, 61b Color filter
101 Color filter
111 Imaging device
114 Solid-state imaging element
116 Signal processing circuit
130 Pixel array section
131 Pixel section
131a Main pixel
131b Sub-pixel
161a, 161b Color filter
181, 201, 221, 241 Color filter

1. A light detecting device, comprising:
a pixel array comprising:
a plurality of main pixels; and
a plurality of sub-pixels having color filters,
wherein more than half of the plurality of main pixels have clear filters, yellow color filters, or no color filters.

2. The light detecting device of claim 1, wherein the plurality of subpixels comprises:
a first group of sub-pixels having color filters of a first color;
a second group of sub-pixels having color filters of a second color; and
a third group of sub-pixels having color filters of a third color.

3. The light detecting device of claim 2, wherein the color filter of the first color comprises a red color filter.

4. The light detecting device of claim 3, wherein:
the color filter of the second color comprises a blue color filter; and
the color filter of the third color comprises a green color filter.

5. The light detecting device of claim 2, wherein:
the color filter of the first color comprises a red color filter;
the color filter of the second color comprises a yellow color filter; and
the color filter of the third color comprises a cyan color filter.

6. The light detecting device of claim 1, wherein a light receiving area of each main pixel of the plurality of main pixels comprises an octagonal shape.

7. The light detecting device of claim 1, wherein each main pixel of the plurality of main pixels has a clear filter or no color filter.

8. The light detecting device of claim 1, wherein at least one main pixel of the plurality of main pixels has a red color filter.

9. The light detecting device of claim 1, further comprising:
a column signal line extending in a column direction;
a pixel control signal line extending in a horizontal direction,
wherein the plurality of main pixels and the plurality of sub-pixels are arranged in a plurality of pixel columns in the column direction and a plurality of pixel rows in the horizontal direction.

10. The light detecting device of claim 9, wherein at least one main pixel of the plurality of main pixels has a red color filter.

11. The light detecting device of claim 9, wherein:
at least one main pixel of the plurality of main pixels has a red color filter; and
at least one main pixel of the plurality of main pixels has a blue color filter.

12. The light detecting device of claim 9, wherein each pixel row of the plurality of pixel rows includes at least one pixel having a clear filter or no color filter.

13. The light detecting device of claim 12, wherein each pixel column of the plurality of pixel columns includes at least one pixel having a clear filter or no color filter.

14. The light detecting device of claim 1, wherein:
more than half of the plurality of main pixels have yellow color filters;
at least one main pixel of the plurality of main pixels has a red color filter; and
at least one main pixel of the plurality of main pixels has a cyan color filter.

15. The light detecting device of claim 1, further comprising a processor configured to generate image data based on signals from the plurality of main pixels and signals from the plurality of sub-pixels.

16. The light detecting device of claim 15, wherein:
the processor is configured to calculate using interpolation:
intermediate main pixel signals for positions between main pixels of the plurality of main pixels; and
intermediate sub-pixel signals for positions between sub-pixels of the plurality of sub-pixels; and
the processor is configured to generate the image data based on signals from the plurality of main pixels, signals from the plurality of subpixels, the intermediate main pixel signals, and the intermediate subpixel signals.

17. A vehicle, comprising:
a light detecting device configured to generate signals;
a processor configured to generate image data based on the signals from the light detecting device;
a vehicle control system configured to control the vehicle based on the image data,
wherein the light detecting device comprises:
a pixel array comprising:
a plurality of main pixels; and
a plurality of sub-pixels having color filters,
wherein more than half of the plurality of main pixels have clear filters, yellow color filters, or no color filters.

18. An automotive camera system comprising:
a lens,
a light detecting device, comprising:
a pixel array comprising:
a plurality of main pixels; and
a plurality of sub-pixels having color filters,
wherein more than half of the plurality of main pixels have clear filters, yellow color filters, or no color filters; and
a processor configured to generate image data based on signals from the plurality of main pixels and signals from the plurality of sub-pixels.

19. The automotive camera system of claim 18, wherein at least one main pixel of the plurality of main pixels has a red color filter.

20. The automotive camera system of claim 18, wherein:
the processor is configured to calculate using interpolation:
intermediate main pixel signals for positions between main pixels of the plurality of main pixels; and
intermediate sub-pixel signals for positions between sub-pixels of the plurality of sub-pixels; and
the processor is configured to generate the image data based on signals from the plurality of main pixels, signals from the plurality of subpixels, the intermediate main pixel signals, and the intermediate subpixel signals.
